(19) United States
(12) Patent Application Publication
(10) Pub. No.: US 2026/0047222 A1
(43) Pub. Date: Feb. 12, 2026

(54) Image Sensing Device

(71) Applicant: SK hynix Inc., Icheon-si (KR)

(72) Inventor: Woo Sung SHIM, Icheon-si (KR)

(21) Appl. No.: 18/733,745

(22) Filed: Jun. 4, 2024

(30) Foreign Application Priority Data
Oct. 4, 2023 (KR) 10-2023-0131701

(51) Int. Cl. H10F 39/00

(52) U.S. Cl. CPC H10F 39/807; H10F 39/8053; H10F 39/8063

(57) ABSTRACT

An image sensing device includes a plurality of pixel blocks arranged in a first direction and a second direction perpendicular to the first direction, each pixel block including a microlens and a plurality of adjacent unit pixels that receives incident light via the microlens and each unit pixel structured to produce an electrical signal in response to received incident light therein, an outer pixel isolation structure disposed between adjacent pixel blocks of the plurality of pixel blocks to isolate the adjacent pixel blocks from each other, and an inner pixel isolation structure disposed between adjacent unit pixels of the unit pixels within each pixel block to isolate the adjacent unit pixels from each other. The inner pixel isolation structure includes a first pixel isolation structure having a different structure from the outer pixel isolation structure.

### PRIORITY CLAIM AND CROSS-REFERENCE TO RELATED APPLICATION

This patent document claims the priority and benefits of Korean patent application No. 10-2023-0131701, filed on Oct. 4, 2023, which is incorporated by reference in its entirety as part of the disclosure of this patent document.

### TECHNICAL FIELD

The technology and implementations disclosed in this patent document generally relate to an image sensing device.

### BACKGROUND

Image sensors are devices that capture images using the properties of semiconductors that respond to light. With the recent development of computer and communication industries, the demand for high-quality, high-performance image sensors is increasing in various electronic devices, such as smartphones, digital cameras, game consoles, Internet of Things (IoT), robots, surveillance cameras, medical micro-cameras, etc.

Image sensing devices may be broadly classified into charge coupled device (CCD)-based image sensing devices and complementary metal oxide semiconductor (CMOS)-based image sensing devices. Recently, CMOS-based image sensing devices are widely used due to the advantage of being able to integrate analog circuits and digital control circuits into a single integrated circuit (IC).

### SUMMARY

Various embodiments of the disclosed technology relate to an image sensing device that includes a pixel isolation structure to isolate photoelectric conversion elements of unit pixels from each other, thereby increasing the use efficiency (quantum efficiency) of incident light.

In an embodiment of the disclosed technology, an image sensing device may include a plurality of pixel blocks arranged in a first direction and a second direction perpendicular to the first direction, each pixel block including a microlens and a plurality of adjacent unit pixels that receives incident light via the microlens and each unit pixel structured to produce an electrical signal in response to received incident light therein; an outer pixel isolation structure disposed between adjacent pixel blocks of the plurality of pixel blocks to isolate the adjacent pixel blocks from each other; and an inner pixel isolation structure disposed between adjacent unit pixels of the unit pixels within each pixel block to isolate the adjacent unit pixels from each other. The inner pixel isolation structure may include a first pixel isolation structure having a different structure from the outer pixel isolation structure.

In another embodiment of the disclosed technology, an image sensing device may include a plurality of unit pixels including a same color filter for filtering incident light to be detected by the unit pixels and configured to share a microlens that direct the incident light into the unit pixels, each of the plurality of unit pixels including a photoelectric conversion element configured to convert received incident light into an electrical signal representing received light at the unit pixel; and a pixel isolation structure disposed between the photoelectric conversion elements of the plurality of unit pixels. The pixel isolation structure may include a first pixel isolation structure disposed to overlap a central portion of the microlens, and a second pixel isolation structure disposed to overlap an edge portion of the microlens and configured to have a different structure from the first pixel isolation structure.

In another embodiment of the disclosed technology, an image sensing device may include a plurality of sub-pixel blocks arranged in a first direction and a second direction perpendicular to the first direction, each of which includes a plurality of unit pixels sharing one microlens; an outer pixel isolation structure disposed between the sub-pixel blocks to isolate the sub-pixel blocks from each other; and an inner pixel isolation structure disposed between the unit pixels within the sub-pixel block to isolate the unit pixels from each other. The inner pixel isolation structure may include a first pixel isolation structure having a different structure from the outer pixel isolation structure.

In another embodiment of the disclosed technology, an image sensing device may include a plurality of unit pixels configured to have the same color filter and configured to share one microlens; and a pixel isolation structure disposed between photoelectric conversion elements of the plurality of unit pixels. The pixel isolation structure may include a first pixel isolation structure disposed to overlap a central portion of the microlens, and a second pixel isolation structure disposed to overlap an edge portion of the microlens and configured to have a different structure from the first pixel isolation structure.

It is to be understood that both the foregoing general description and the following detailed description of the disclosed technology are illustrative and explanatory and are intended to provide further explanation of the disclosure as claimed.

### BRIEF DESCRIPTION OF THE DRAWINGS

The above and other features and beneficial aspects of the disclosed technology will become readily apparent with reference to the following detailed description when considered in conjunction with the accompanying drawings.

FIG. 1 is a block diagram illustrating an example of an image sensing device based on some implementations of the disclosed technology.

FIG. 2 is a schematic diagram illustrating an example of a 2-dimensional representation of a set of pixel blocks in a pixel region shown in FIG. 1 based on some implementations of the disclosed technology.

FIG. 3 is an enlarged plan view illustrating an example of a pixel isolation structure of a region “A” shown in FIG. 2 based on some implementations of the disclosed technology.

FIG. 4A is a cross-sectional view illustrating an example of a pixel block taken along the line X1-X1′ shown in FIG. 2 based on some implementations of the disclosed technology.

FIG. 4B is a cross-sectional view illustrating an example of the pixel block taken along the line X2-X2′ shown in FIG. 2 based on some implementations of the disclosed technology.

FIG. 4C is a cross-sectional view illustrating an example of the pixel block taken along the line X3-X3′ shown in FIG. 2 based on some implementations of the disclosed technology.

FIG. 5 is a schematic diagram illustrating an example of a 2-dimensional representation of a set of pixel blocks based on some implementations of the disclosed technology.

FIG. 6 is an enlarged plan view illustrating an example of a pixel isolation structure of a region “B” shown in FIG. 5 based on some implementations of the disclosed technology.

FIGS. 7A to 7E are schematic diagrams illustrating examples of 2-dimensional representations of inner pixel isolation structures based on some implementations of the disclosed technology.

### DETAILED DESCRIPTION

This patent document provides implementations and examples of an image sensing device that may be used to substantially address one or more technical or engineering issues and mitigate limitations or disadvantages encountered in some other image sensing devices. The disclosed technology can be implemented in some embodiments to provide an image sensing device capable of increasing the use efficiency (quantum efficiency) of incident light by providing a pixel isolation structure is specially designed to isolate photoelectric conversion elements of unit pixels from each other.

Reference will now be made in detail to certain embodiments, examples of which are illustrated in the accompanying drawings. Wherever possible, the same reference numbers will be used throughout the drawings to refer to the same or similar parts. In the following description, a detailed description of related known configurations or functions incorporated herein will be omitted to avoid obscuring the subject matter.

Hereinafter, various embodiments will be described with reference to the accompanying drawings. However, it should be understood that the disclosed technology is not limited to specific embodiments, but includes various modifications, equivalents and/or alternatives of the embodiments. The embodiments of the disclosed technology may provide a variety of effects capable of being directly or indirectly recognized through the disclosed technology.

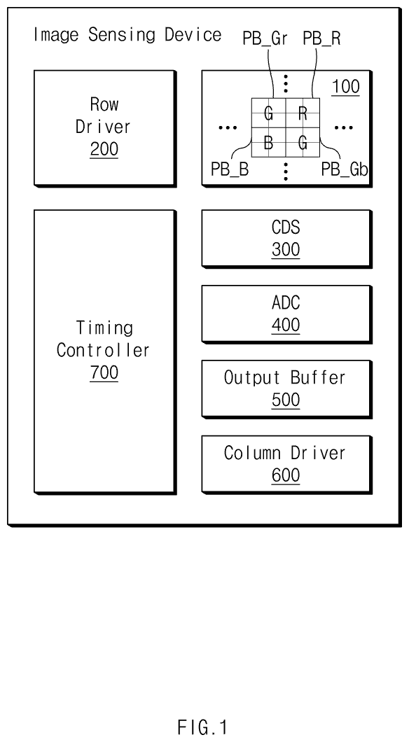

FIG. 1 is a block diagram illustrating an example of an image sensing device based on some implementations of the disclosed technology.

Referring to FIG. 1, the image sensing device may include a pixel region 100, a row driver 200, a correlated double sampler (CDS) 300, an analog-digital converter (ADC) 400, an output buffer 500, a column driver 600, and a timing controller 700. The components of the image sensing device illustrated in FIG. 1 are discussed by way of example only, and this patent document encompasses numerous other changes, substitutions, variations, alterations, and modifications. In this patent document, the word “pixel” can be used to indicate an image sensing pixel that is structured to detect incident light to generate electrical signals carrying images in the incident light.

The pixel region 100 may include a plurality of pixel blocks (PB_R, PB_Gr, PB_Gb, PB_B) consecutively arranged in rows and columns. The pixel blocks (PB_R, PB_Gr, PB_Gb, PB_B) may be arranged adjacent to each other in a (2×2) matrix structure in a Bayer pattern. Each of the pixel blocks (PB_R, PB_Gr, PB_Gb, PB_B) may include a structure in which a plurality of unit pixels having the same color is arranged adjacent to each other in an (N×N) matrix (where N is a natural number of 2 or greater). Each unit pixel may include a photoelectric conversion element (e.g., a photodiode PD) for photoelectrically converting incident light to generate an electrical signal (i.e., a pixel signal). One microlens may be formed in each pixel block (PB_R, PB_Gr, PB_Gb, PB_B). The structure of these pixel blocks (PB_R, PB_Gr, PB_Gb, PB_B) will be described in more detail later.

The pixel region 100 may receive driving signals (for example, a row selection signal, a reset signal, a transmission (or transfer) signal, etc.) from the row driver 200. Upon receiving the driving signals, the unit pixels may be activated to perform the operations corresponding to the row selection signal, the reset signal, and the transfer signal.

The row driver 200 may activate the pixel region 100 to perform certain operations on the unit pixels in the corresponding row based on control signals provided by controller circuitry such as the timing controller 700. In some implementations, the row driver 200 may select one or more pixel groups arranged in one or more rows of the pixel region 100. The row driver 200 may generate a row selection signal to select one or more rows from among the plurality of rows. The row driver 200 may sequentially enable the reset signal and the transfer signal for the unit pixels arranged in the selected row. The pixel signals generated by the unit pixels arranged in the selected row may be output to the correlated double sampler (CDS) 300.

The correlated double sampler (CDS) 300 may remove undesired offset values of the unit pixels using correlated double sampling. In one example, the correlated double sampler (CDS) 300 may remove the undesired offset values of the unit pixels by comparing output voltages of pixel signals (of the unit pixels) obtained before and after photocharges generated by incident light are accumulated in the sensing node (i.e., a floating diffusion (FD) node). As a result, the CDS 300 may obtain a pixel signal generated only by the incident light without causing noise. In some implementations, upon receiving a clock signal from the timing controller 700, the CDS 300 may sequentially sample and hold voltage levels of the reference signal and the pixel signal, which are provided to each of a plurality of column lines from the pixel region 100. That is, the CDS 300 may sample and hold the voltage levels of the reference signal and the pixel signal which correspond to each of the columns of the pixel region 100. In some implementations, the CDS 300 may transfer the reference signal and the pixel signal of each of the columns as a correlate double sampling (CDS) signal to the ADC 400 based on control signals from the timing controller 700.

The ADC 400 is used to convert analog CDS signals received from the CDS 300 into digital signals. In some implementations, the ADC 400 may be implemented as a ramp-compare type ADC. The analog-to-digital converter (ADC) 400 may compare a ramp signal received from the timing controller 700 with the CDS signal received from the CDS 300, and may thus output a comparison signal indicating the result of comparison between the ramp signal and the CDS signal. The analog-to-digital converter (ADC) 400 may count a level transition time of the comparison signal in response to the ramp signal received from the timing controller 700, and may output a count value indicating the counted level transition time to the output buffer 500.

The output buffer 500 may temporarily store column-based image data provided from the ADC 400 based on control signals of the timing controller 700. The image data received from the ADC 400 may be temporarily stored in the output buffer 500 based on control signals of the timing controller 700. The output buffer 500 may provide an interface to compensate for data rate differences or transmission rate differences between the image sensing device and other devices.

The column driver 600 may select a column of the output buffer 500 upon receiving a control signal from the timing controller 700, and sequentially output the image data, which are temporarily stored in the selected column of the output buffer 500. In some implementations, upon receiving an address signal from the timing controller 700, the column driver 600 may generate a column selection signal based on the address signal, may select a column of the output buffer 500 using the column selection signal, and may control the image data received from the selected column of the output buffer 500 to be output as an output signal.

The timing controller 700 may generate signals for controlling operations of the row driver 200, the ADC 400, the output buffer 500 and the column driver 600. The timing controller 700 may provide the row driver 200, the column driver 600, the ADC 400, and the output buffer 500 with a clock signal required for the operations of the respective components of the image sensing device, a control signal for timing control, and address signals for selecting a row or column. In some implementations, the timing controller 700 may include a logic control circuit, a phase lock loop (PLL) circuit, a timing control circuit, a communication interface circuit and others.

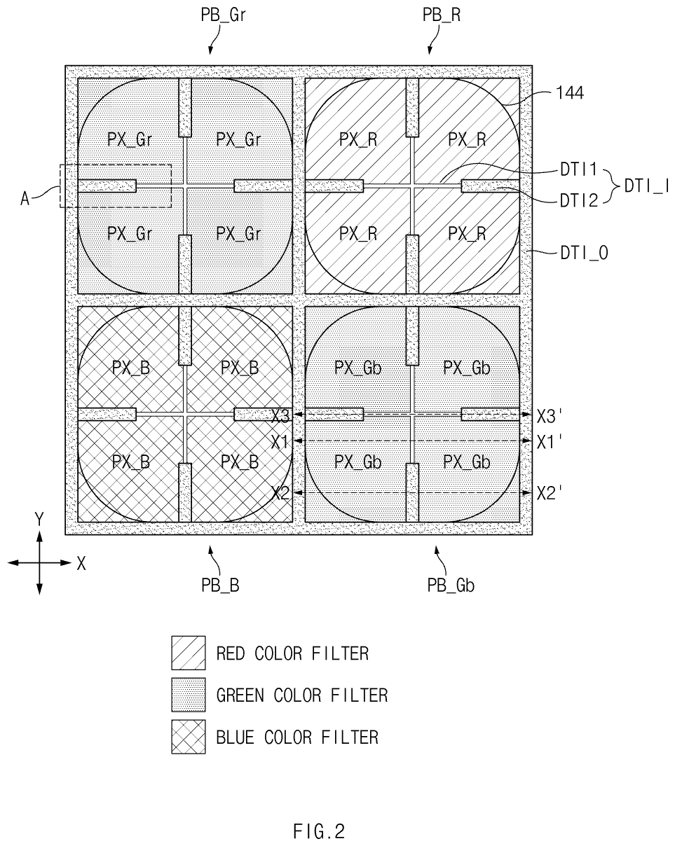

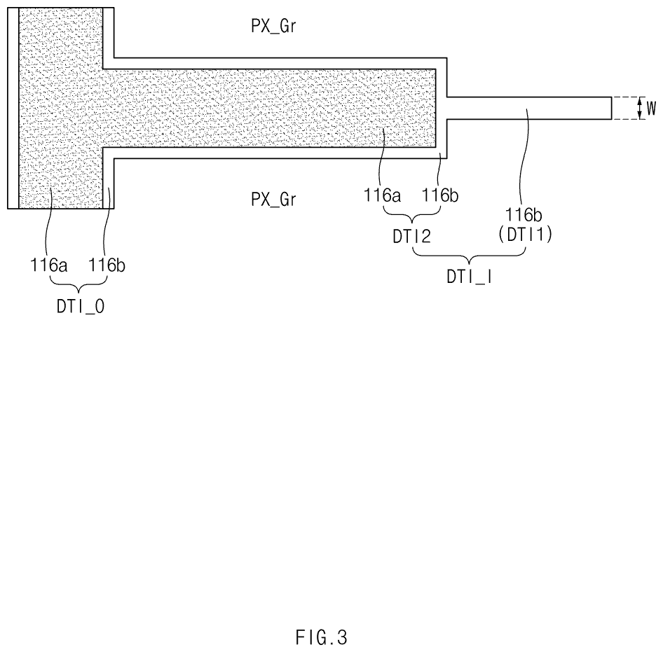

FIG. 2 is a schematic diagram illustrating an example of a 2-dimensional representation of a set of pixel blocks in the pixel region 100 shown in FIG. 1 with one implementation of the disclosed pixel isolation structure based on some implementations of the disclosed technology. FIG. 3 is an enlarged plan view illustrating an example of a pixel isolation structure of a region “A” shown in FIG. 2 based on some implementations of the disclosed technology.

Referring to FIGS. 2 and 3, the pixel region 100 may include a plurality of pixel blocks (PB_R, PB_Gr, PB_Gb, PB_B) consecutively arranged in the row and column directions.

Each pixel block (PB_R, PB_Gr, PB_Gb, PB_B) may include a plurality of unit pixels having the same color and arranged adjacent to each other in an (N×N) array (where N is a natural number of 2 or greater). Each pixel block (PB_R, PB_Gr, PB_Gb, PB_B) may include a microlens 144.

For example, the pixel block (PB_R) may include four unit pixels (PX_R), and each of the four unit pixels (PX_R) may include a red color filter. Here, the four unit pixels (PX_R) may be arranged adjacent to each other in a (2×2) matrix, and may share one microlens 144. The pixel block (PB_Gr) may include four unit pixels (PX_Gr), and each of the four unit pixels (PX_Gr) may include a green color filter. Here, the four unit pixels (PX_Gr) may be arranged adjacent to each other in a (2×2) matrix, and may share one microlens 144. The sub-pixel block (PB_Gb) may include four unit pixels (PX_Gb), and each of the four unit pixels (PX_Gb) may include a green color filter. Here, the four unit pixels (PX_Gb) may be arranged adjacent to each other in a (2×2) matrix, and may share one microlens 144. The sub-pixel block (PB_B) may include four unit pixels (PX_B), and each of the four unit pixels (PX_B) may include a blue color filter. Here, the four unit pixels (PX_B) may be arranged adjacent to each other in a (2×2) matrix, and may share one microlens 144. These pixel blocks (PB_R, PB_Gr, PB_Gb, PB_B) may be arranged in a Bayer pattern.

Each unit pixel (PX_R, PX_Gr, PX_Gb, PX_B) may include a photoelectric conversion element within the substrate, and adjacent photoelectric conversion elements may be physically isolated from each other by a pixel isolation structure. In some implementations, the term “photoelectric conversion element” can be used to indicate any component that can convert incident light into electrical signals, such as photodiodes. The pixel isolation structure may be built into the pixel region 100 and may be supported by or formed in the substrate to include (1) an outer pixel isolation structure (DTI_O) to outside each pixel block and to separate adjacent pixel blocks, and (2) an inner pixel isolation structure (DTI_I) located within a pixel block at a boundary of two adjacent unit pixels within the pixel block. The outer pixel isolation structure (DTI_O) and the inner pixel isolation structure (DTI_I) may include a Front Deep Trench Isolation (FDTI) or Back Deep Trench Isolation (BDTI) structure. For example, the outer pixel isolation structure (DTI_O) and the inner pixel isolation structure (DTI_I) may include an FDTI or BDTI structure formed to penetrate the substrate.

In the implementation example shown in FIG. 2, the outer pixel isolation structure (DTI_O) of the pixel isolation structure in the pixel region 100 may be disposed between adjacent pixel blocks (PB_R, PB_Gr, PB_Gb, PB_B), and may be formed to surround each pixel block (PB_R, PB_Gr, PB_Gb, PB_B). The outer pixel isolation structure (DTI_O) may include a conductive material 116a and an insulation material 116b. For example, the outer pixel isolation structure (DTI_O) may include an insulation material 116b formed at sidewalls of a pixel isolation trench formed by etching the substrate, and a conductive material 116a disposed between the insulation materials 116b to gap-fill the pixel isolation trench. The conductive material 116a may include doped (e.g., ion-implanted) polysilicon or a metallic material. The insulation material 116b may include a material having a lower light absorption rate than the conductive material 116a. For example, the insulation material 116b may include an oxide layer.

The inner pixel isolation structure (DTI_I) may be located within each pixel block (PB_R, PB_Gr, PB_Gb, PB_B) and may be disposed between adjacent unit pixels (PX_R, PX_Gr, PX_Gb, PX_B) to provide some isolation between adjacent unit pixels. In the specific example shown in FIG. 2, the inner pixel isolation structure (DTI_I) may include a first pixel isolation structure (DTI1) near the center of each pixel block and second pixel isolation structures (DTI2) connected to the outer pixel isolation structure (DTI_O).

The first pixel isolation structure (DTI1) may be disposed in a partial region between adjacent unit pixels (PX_R, PX_Gr, PX_Gb, and PX_B) within each pixel block (PB_R, PB_Gr, PB_Gb, PB_B). For example, the first pixel isolation structure (DTI1) may be disposed to overlap the central portion of the microlens 144 within each pixel block (PB_R, PB_Gr, PB_Gb, PB_B). The central portion of the microlens 144 may include a region located within a predetermined distance from the center point of the microlens 144.

The first pixel isolation structure (DTI1) may be connected to the second pixel isolation structures (DTI2), and may extend from each of the second pixel isolation structures (DTI2) to the center of each of the pixel blocks (PB_R, PB_Gr, PB_Gb, PB_B). For example, the first pixel isolation structure (DTI1) disposed between the second pixel isolation structures (DTI2) may be formed in a cross shape that includes (1) a portion extending in a line shape in a first direction (e.g., an X-axis direction) and (2) a portion extending in a line shape in a second direction (e.g., a Y-axis direction) that are arranged to cross each other at the center of each of the pixel blocks (PB_R, PB_Gr, PB_Gb, PB_B).

The first pixel isolation structure (DTI1) may be formed to have a smaller width (e.g., a shorter length in the minor axis direction) than each of the second pixel isolation structures (DTI2). For example, the width (W) of the first pixel isolation structure (DTI1) may be less than or equal to twice a thickness of the insulation material 116b of the second pixel isolation structures (DTI2).

The first pixel isolation structure (DTI1) may include the insulation material 116b. For example, the first pixel isolation structure (DTI1) may include a structure in which the pixel isolation trench formed by etching the substrate is gap-filled with the insulation material 116b without the conductive material 116a.

The second pixel isolation structures (DTI2) may be disposed in some regions between adjacent unit pixels (PX_R, PX_Gr, PX_Gb, PX_B) within each pixel block (PB_R, PB_Gr, PB_Gb, PB_B). For example, the second pixel isolation structure (DTI2) may be disposed in a region that overlaps the edge portion of the microlens 144 within each pixel block (PB_R, PB_Gr, PB_Gb, PB_B). The edge portion of the microlens 144 may refer to a region located outside the central portion of the microlens 144.

Both ends of each of the second pixel isolation structures (DTI2) may be connected to the outer pixel isolation structure (DTI_O) and the first pixel isolation structure (DTI1). For example, the second pixel isolation structures (DTI2) may be formed in a line shape extending from the outer pixel isolation structure (DTI_O) to the first pixel isolation structure (DTI1). The second pixel isolation structures (DTI2) may have the same width as the outer pixel isolation structure (DTI_O).

Each of the second pixel isolation structures (DTI2) may include the conductive material 116a and the insulation material 116b. For example, the second pixel isolation structures (DTI2) may include the same structure as the outer pixel isolation structure (DTI_O).

The first pixel isolation structure (DTI1) may be formed when the insulation material 116b of the outer pixel isolation structure (DTI_O) and the insulation material 116b of the second pixel isolation structures (DTI2) are formed. For example, when forming a trench (hereinafter referred to as a “first pixel isolation trench”) for forming the first pixel isolation structure (DTI1) and trenches (hereinafter referred to as “second pixel isolation trenches”) for forming the second pixel isolation structures (DTI2), the width of the first pixel isolation trench may be less than or equal to twice the thickness of the insulation material 116b to be formed in each of the second pixel isolation structures (DTI2). Accordingly, when an insulation-layer formation process is performed on the sidewalls of the first and second pixel isolation trenches, the first pixel isolation trench may be gap-filled with the insulation material 116b whereas the insulation material 116b is formed only at the sidewalls of the second pixel trenches.

For example, the insulation material 116b may be formed by oxidizing the sidewalls of the first and second pixel isolation trenches through a heat treatment process. Alternatively, the insulation material 116b may be formed at the sidewalls of the first and second pixel isolation trenches through a deposition process.

When each of the second pixel isolation trenches is gap-filled with the conductive material 116a in a situation in which the first pixel isolation trench is gap-filled with the insulation material 116b, the conductive material 116a may be included in the second pixel isolation structures (DTI2) but not in the first pixel isolation structure (DTI1) as shown in FIG. 3. The outer pixel isolation structure (DTI_O) may be formed in the same manner as the second pixel isolation structures (DTI2).

In an image sensing device that includes the trench structure, such as DTI, formed by etching the substrate, in order to control dark noise that may occur at the interface of the trench, a conductive material may be formed in the trench and a negative voltage may be applied to the corresponding conductive material. However, in an embodiment of the disclosed technology, in a structure in which the plurality of unit pixels (PX_R, PX_Gr, PX_Gb, PX_B) of each of the pixel blocks (PB_R, PB_Gr, PB_Gb, PB_B) share one microlens, a large amount of incident light received through the microlens 144 may be concentrated at the central portion of the pixel blocks (PB_R, PB_Gr, PB_Gb, PB_B). In some implementations, in a structure in which the plurality of unit pixels (PX_R) of the pixel block (PB_R) shares one microlens, a large amount of incident light received through the microlens 144 may be concentrated at the central portion of the pixel block (PB_R). In a structure in which the plurality of unit pixels (PX_Gr) of the pixel block (PB_Gr) shares one microlens, a large amount of incident light received through the microlens 144 may be concentrated at the central portion of the pixel block (PB_Gr). In a structure in which the plurality of unit pixels (PX_Gb) of the pixel block (PB_Gb) shares one microlens, a large amount of incident light received through the microlens 144 may be concentrated at the central portion of the pixel block (PB_Gb). In a structure in which the plurality of unit pixels (PX_B) of the pixel block (PB_B) shares one microlens, a large amount of incident light received through the microlens 144 may be concentrated at the central portion of the pixel block (PB_B).

Therefore, when the pixel isolation structure in the central portion of each pixel block (PB_R, PB_Gr, PB_Gb, PB_B) contains a conductive material, the conductive material absorbs incident light well. As a result, a large amount of incident light may be absorbed into the conductive material without being converted into photocharges (electrons), deteriorating the use efficiency (quantum efficiency) of incident light.

In some implementations of the disclosed technology, a conductive material for controlling dark noise may be included in a pixel isolation structure formed in a region at which incident light is not concentrated, and a conductive material may not be formed in a pixel isolation structure formed in a region at which incident light is concentrated, thereby increasing quantum efficiency of the image sensing device.

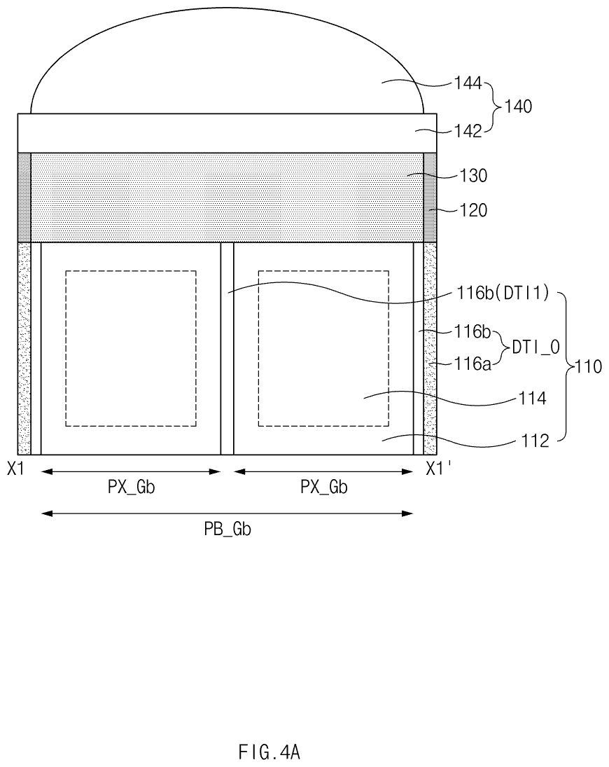

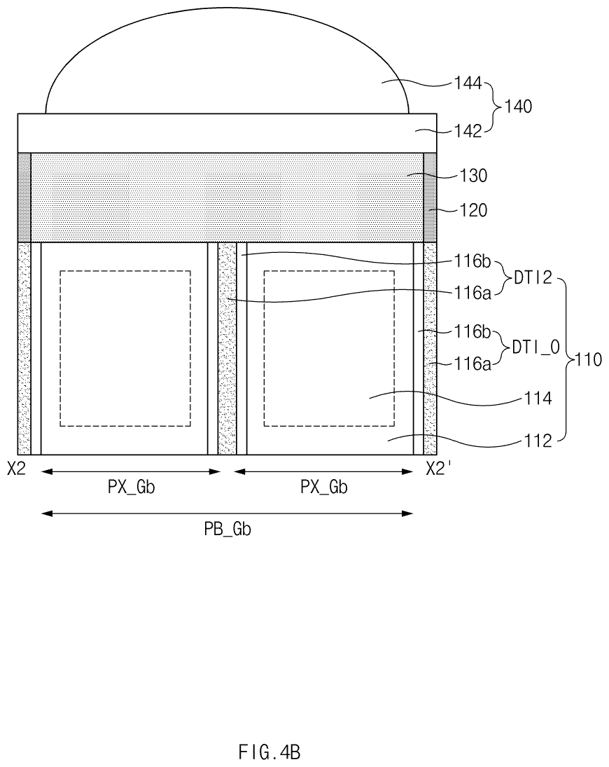

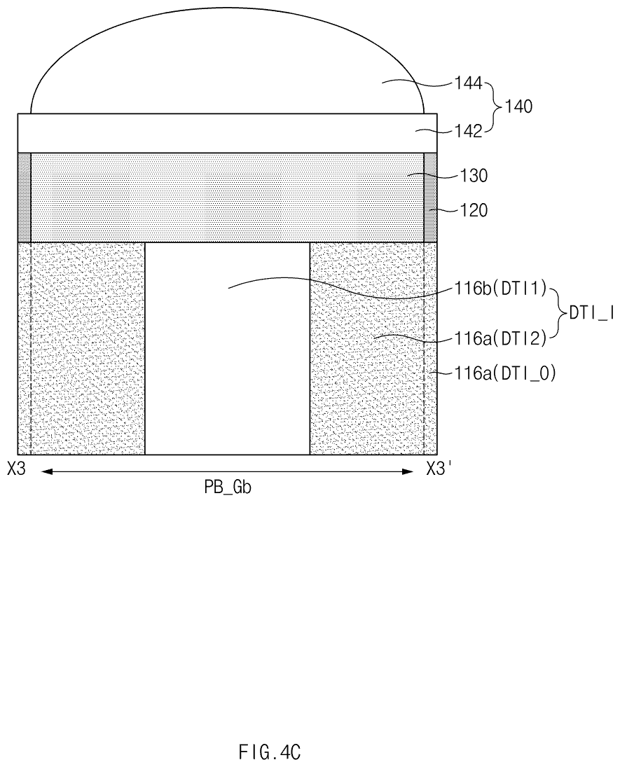

FIG. 4A is a cross-sectional view illustrating an example of a pixel block taken along the line X1-X1′ shown in FIG. 2 based on some implementations of the disclosed technology. FIG. 4B is a cross-sectional view illustrating an example of the pixel block taken along the line X2-X2′ shown in FIG. 2 based on some implementations of the disclosed technology. FIG. 4C is a cross-sectional view illustrating an example of the pixel block taken along the line X3-X3′ shown in FIG. 2 based on some implementations of the disclosed technology.

In some implementations, the plurality of pixel blocks (PB_R, PB_Gr, PB_Gb, PB_B) has the same structure except for different color filters. Accordingly, the structures of the pixel blocks (PB_R, PB_Gr, PB_B) may have the same structure as the pixel block (PB_Gb) discussed below.

Referring to FIGS. 4A to 4C, the pixel region 100 may include a substrate layer 110, a grid structure 120, a color filter layer 130, and a lens layer 140.

The substrate layer 110 may include a substrate 112, photoelectric conversion elements 114, and pixel isolation structures (DTI_O, DTI_I). The substrate layer 110 may include a first surface (e.g., a back surface) and a second surface (e.g., a front surface) facing or opposite to the first surface. In some implementations, light is incident upon the first surface, and a grid structure 120, a color filter layer 130, and a lens layer 140 may be formed over the first surface. Pixel transistors (not shown) may be used to read out photocharges generated by the photoelectric conversion element 114 of the corresponding unit pixel, and may be formed in each unit pixel region of the second surface.

The substrate 112 may include a semiconductor substrate containing monocrystalline silicon. The substrate 112 may contain P-type impurities.

The photoelectric conversion elements 114 may be formed in the substrate 112 to respectively correspond to the unit pixels. The photoelectric conversion elements 114 may photoelectrically convert light incident through the lens layer 140 and the color filter layer 130 to generate photocharges. The photoelectric conversion elements 114 may include N-type impurities.

The pixel isolation structures (DTI_O, DTI_I) may be disposed between adjacent photoelectric conversion elements 114 within the substrate 112 to isolate the photoelectric conversion elements 114 from each other. The pixel isolation structure (DTI_O, DTI_I) may include the outer pixel isolation structure (DTI_O) located outside each of the pixel blocks (PB_R, PB_Gr, PB_Gb, PB_B), and the inner pixel isolation structure (DTI_I) located inside each of the pixel blocks (PB_R, PB_Gr, PB_Gb, PB_B). The inner pixel isolation structure (DTI_I) may include a first pixel isolation structure (DTI1) and a second pixel isolation structure (DTI2). The pixel isolation structures (DTI_O, DTI_I) may include FDTI or BDTI structures penetrating the substrate 112.

The outer pixel isolation structure (DTI_O) may be formed between the photoelectric conversion elements 114 of the adjacent pixel blocks (PB_R, PB_Gr, PB_Gb, PB_B) within the substrate 112, and the inner pixel isolation structure (DTI_I) may be formed between the adjacent photoelectric conversion elements 114 within each pixel block (PB_R, PB_Gr, PB_Gb, PB_B).

The outer pixel isolation structure (DTI_O) and the second pixel isolation structure (DTI2) may include the same structure. For example, the outer pixel isolation structure (DTI_O) and the second pixel isolation structure (DTI2) may include an insulation material 116b formed at the sidewalls of the pixel isolation trench, and a conductive material 116a formed between the insulation materials 116b to gap-fill the pixel isolation trench.

In the inner pixel isolation structure (DTI_I), the first pixel isolation structure (DTI1) may be disposed between the photoelectric conversion elements 114 to overlap the central portion of the microlens 144, and the second pixel isolation structure (DTI2) may be disposed between the photoelectric conversion elements 114 to overlap the edge portion of the microlens 144.

The first pixel isolation structure (DTI1) may be formed to have a smaller width than the second pixel isolation structures (DTI2). The first pixel isolation structure (DTI1) may have a structure (e.g., trench) that is gap-filled with the insulation material 116b without the conductive material 116a. The first pixel isolation structure (DTI1) may be formed when the insulation material 116b of the outer pixel isolation structure (DTI_O) and the insulation material 116b of the second pixel isolation structure (DTI2) are formed.

The grid structure 120 may be formed between the color filters on the first surface of the substrate 112 to prevent crosstalk between the color filters. For example, the grid structure 120 may be formed between color filters of adjacent pixel blocks (PB_R, PB_Gr, PB_Gb, PB_B) without being formed within each pixel block (PB_R, PB_Gr, PB_Gb, PB_B). The grid structure 120 may include metal (e.g., tungsten).

The color filter layer 130 may include color filters filter visible light from light incident through the lens layer 140. Although FIGS. 4A to 4C shows one color filter only, the color filter layer 130 may also include a red color filter that is formed in the pixel block (PB_R) and transmits red visible light having a first wavelength band, green color filters formed in the pixel blocks (PB_Gr, PB_Gb) to transmit green visible light having a second wavelength band shorter than the first wavelength band, and a blue color filter formed in the pixel block (PB_B) to transmit blue visible light having a third wavelength band shorter than the second wavelength band. The color filters may be disposed between grid structures 120. One color filter shared by four unit pixels may be formed in each pixel block (PB_R, PB_Gr, PB_Gb, PB_B).

The lens layer 140 may include an over-coating layer 142 and a plurality of microlenses 144. The over-coating layer 142 may be formed over the color filter layer 130. The over-coating layer 142 may serve as a planarization layer to flatten an uneven surface (e.g., surface with steps) caused by the color filter layer 130. The microlenses 144 may be formed over the over-coating layer 142, may converge incident light, and may transmit the converged light to the substrate layer 110. Each of the microlenses 144 may be formed per pixel block (PB_R, PB_Gr, PB_Gb, PB_B). The over-coating layer 142 and the microlenses 144 may be formed of the same materials.

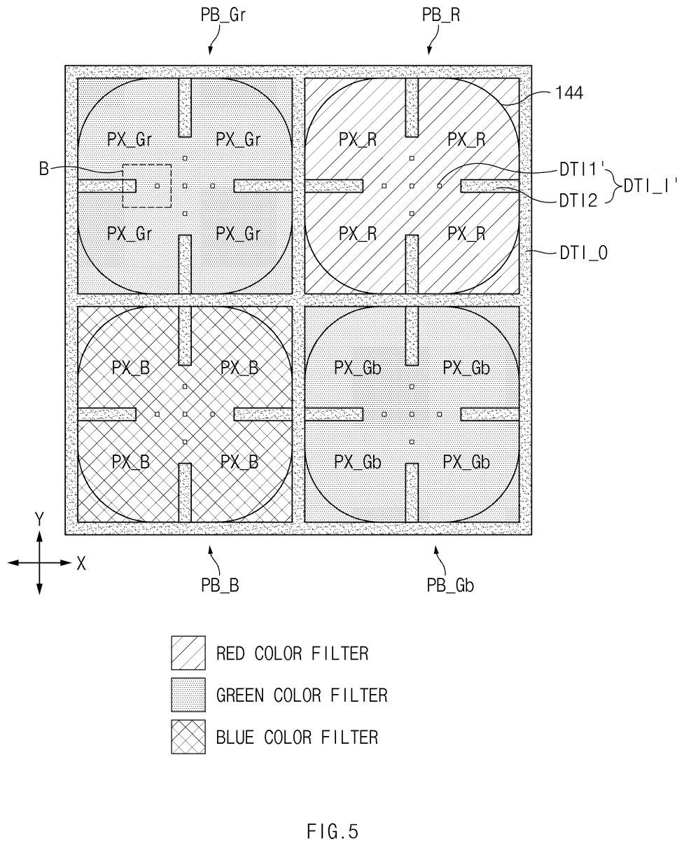

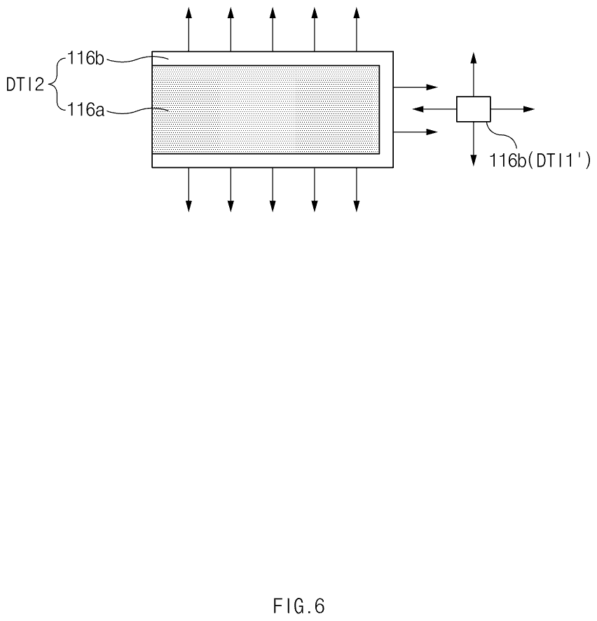

FIG. 5 is a schematic diagram illustrating an example of a 2-dimensional representation of a set of pixel blocks based on some implementations of the disclosed technology. FIG. 6 is an enlarged plan view illustrating an example of a pixel isolation structure of a region “B” shown in FIG. 5 based on some implementations of the disclosed technology.

Referring to FIG. 5, in an embodiment of the disclosed technology, pixel blocks may have the same structure as the examples shown in FIGS. 2 and 3 except for the first pixel isolation structure formed at the central portion of each pixel block (PB_R, PB_Gr, PB_Gb, PB_B).

Referring to FIGS. 5 and 6, the pixel isolation structure (DTI_O, DTI_I′) may include an outer pixel isolation structure (DTI_O) and an inner pixel isolation structure (DTI_I′). The inner pixel isolation structure (DTI_I′) may include first pixel isolation structures (DTI1′) and second pixel isolation structures (DTI2).

The first pixel isolation structures (DTI1′) may include island-type pixel isolation structures located to overlap the central portion of the microlens 144 within each of the pixel blocks (PB_R, PB_Gr, PB_Gb, PB_B). The first pixel isolation structures (DTI1′) may be arranged to be spaced apart from each other by a predetermined distance in the first direction (e.g., X-axis direction) and the second direction (e.g., Y-axis direction) between the second pixel isolation structures (DTI2). Although FIG. 5 shows three first pixel isolation structures (DTI1′) are arranged in each of the first direction and the second direction by way of example, other implementations are also possible. In addition, although FIG. 5 shows that each 2-D representation of the first pixel isolation structures (DTI1′) has a square shape, other implementations are also possible. For example, the first pixel isolation structures (DTI1′) may be formed in a rectangular, diamond, or circular shape.

Each of the first pixel isolation structures (DTI1′) may include a structure in which the pixel isolation trench formed to penetrate the substrate is gap-filled with the insulation material 116b without the conductive material 116a. The insulation material 116b of the first pixel isolation structures (DTI1′) may be formed when the insulation material 116b of the outer pixel isolation structure (DTI_O) and the insulation material 116b of the second pixel isolation structures (DTI2) are formed. The pixel isolation trenches (hereinafter referred to as “third pixel isolation trenches”) in which the first pixel isolation structures (DTI1′) are formed may have a predetermined size such that each of the third pixel isolation trenches can be gap-filled with the insulation material 116b of the predetermined size when the insulation material 116b of the outer pixel isolation structure (DTI_O) and the insulation materials 116b of the second pixel isolation structures (DTI2) are formed. For example, the length of each of the third pixel isolation trenches in the first or second direction may be less than or equal to twice the thickness of the insulation material 116b to be formed in the second pixel isolation structures (DTI2).

In an image sensing device that includes the trench structure, such as DTI, formed by etching the substrate, a passivation region formed by implanting ions (e.g., P-type ions) into the sidewalls of the trench may be formed to reduce dark noise that may occur at the interface of the trench. A distance between each first pixel isolation structure (DTI1′) and each second pixel isolation structures (DTI2) adjacent to the first pixel isolation structure (DTI1′) and a distance between the first pixel isolation structures (DTI1′) adjacent to each other may be less than or equal to twice the length (e.g., the length of each arrow shown in FIG. 6) of the passivation region in which ions for reducing dark noise are implanted. For example, each of the first pixel isolation structures (DTI1′) and each of the second pixel isolation structures (DTI2) may be spaced apart from each other by a predetermined distance that allows the passivation regions formed at the sidewalls of the third pixel isolation trenches and the second pixel isolation trenches to be connected to each other through a plasma doping (PLAD) process. Accordingly, the unit pixels (PX_R, PX_Gr, PX_Gb, PX_B) may be surrounded by the ion implantation region (e.g., passivation regions) thereof, so that the unit pixels (PX_R, PX_Gr, PX_Gb, PX_B) can be isolated from each other.

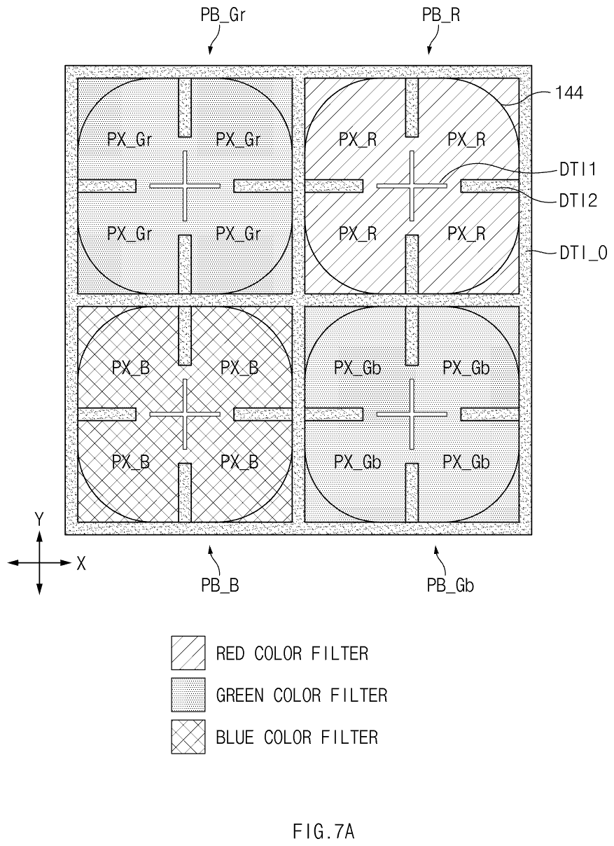

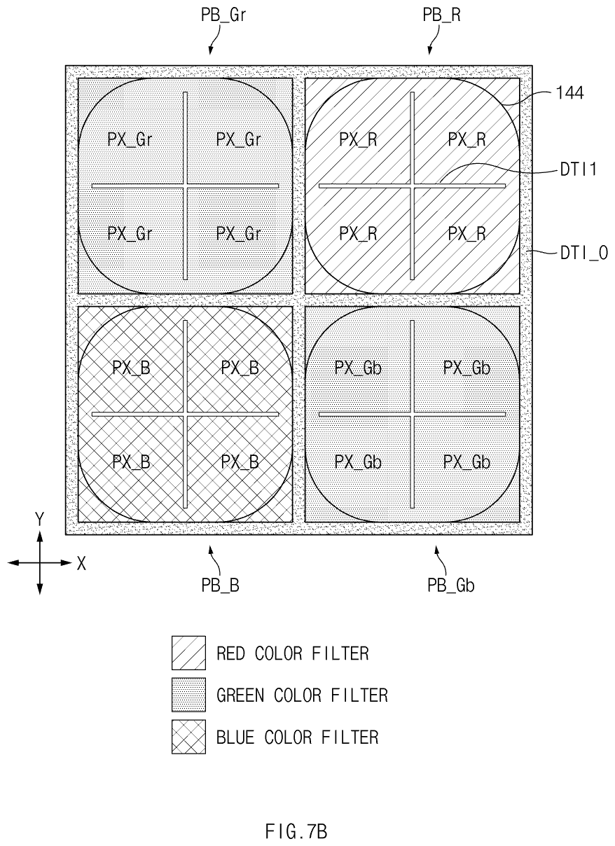

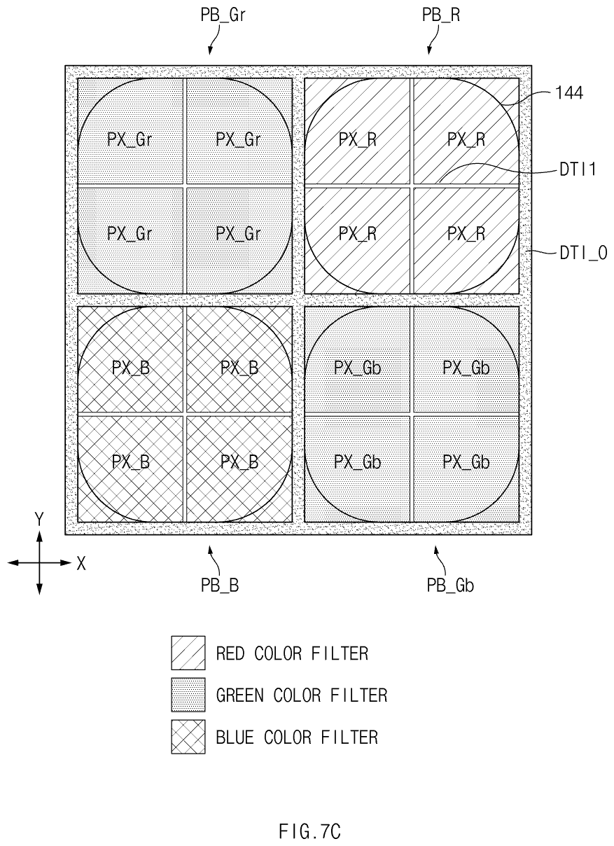

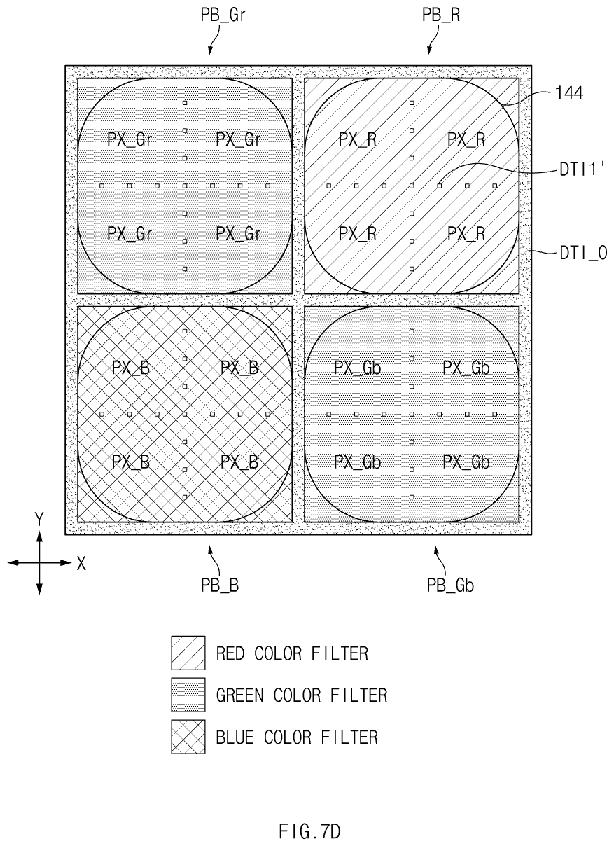

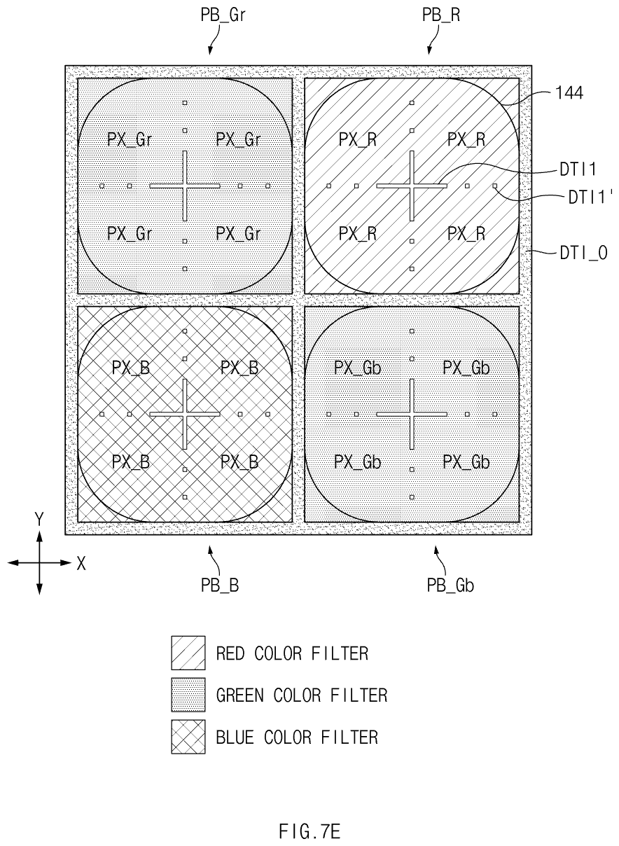

FIGS. 7A to 7E are schematic diagrams illustrating examples of 2-dimensional representations of inner pixel isolation structures based on some implementations of the disclosed technology.

Referring to FIGS. 7A to 7E, the inner pixel isolation structures formed in each of the pixel blocks (PB_R, PB_Gr, PB_Gb, PB_B) may be formed in a shape in which a pixel isolation structure including conductive materials and a pixel isolation structure including no conductive materials are combined with each other in various ways. Hereinafter, for convenience of explanation, only the differences from what is discussed above, are described with reference to FIGS. 7A to 7E. In addition, among the inner pixel isolation structures that do not contain conductive materials, pixel isolation structures having a cross shape will hereinafter be collectively referred to as “first pixel isolation structure (DTI1)” for convenience of description, and pixel isolation structures having an island-type square shape will hereinafter be collectively referred to as “first pixel isolation structure (DTI1′)” for convenience of description. In addition, the inner pixel isolation structure including conductive materials will hereinafter be collectively referred to as “second pixel isolation structure (DTI2)”.

Referring to FIG. 7A, the inner pixel isolation structure may include a first pixel isolation structure (DTI1) and the second pixel isolation structures (DTI2). As shown in FIG. 2, the first pixel isolation structure (DTI1) may be formed in a cross shape at the central portion of each of the pixel blocks (PB_R, PB_Gr, PB_Gb, PB_B) so as to overlap the central portion of the microlens 144. The first pixel isolation structure (DTI1) may be formed to be spaced apart from the second pixel isolation structures (DTI2). In some implementations, as described above, the first pixel isolation structure (DTI1) and each of the second pixel isolation structures (DTI2) may be formed to be spaced apart from each other by a predetermined distance that allows ion implantation regions formed by ions implanted through the PLAD process to contact each other.

Referring to FIG. 7B, the inner pixel isolation structure may include only the first pixel isolation structure (DTI1) formed in a cross shape. For example, the first pixel isolation structure (DTI1) may be formed in a cross shape that includes a portion extending in a line shape in the first direction and a portion extending in a line shape in the second direction that are arranged to cross each other at the center of each of the pixel blocks (PB_R, PB_Gr, PB_Gb, PB_B), so that the first pixel isolation structure (DTI1) formed in the cross shape can be formed to overlap not only the central portion of the microlens 144 but also the edge portion of the microlens 144.

The first pixel isolation structure (DTI1) may be formed to be spaced a certain distance away from the outer pixel isolation structure (DTI_O). In some implementations, as described above, the first pixel isolation structure (DTI1) and the outer pixel isolation structure (DTI_O) may be formed to be spaced apart from each other by a predetermined distance that allows the ion implantation regions formed by ions implanted through the PLAD process may come into contact with each other.

Referring to FIG. 7C, unlike the structure of FIG. 7B, the inner pixel isolation structure may be formed such that the first pixel isolation structure (DTI1) is connected to the outer pixel isolation structure (DTI_O).

Referring to FIG. 7D, the inner pixel isolation structure may include only the island-type first pixel isolation structures (DTI1′) that are spaced apart from each other by a predetermined distance. All of the first pixel isolation structures (DTI1′) may have the same size. The first pixel isolation structures (DTI1′) and the outer pixel isolation structures (DTI_O) may be formed to be spaced apart from each other by a predetermined distance that allows ion implantation regions formed by ions implanted through the PLAD process to contact each other.

Referring to FIG. 7E, the inner pixel isolation structure may be formed in a shape in which first pixel isolation structures (DTI1, DTI1′) having different structures are combined. Referring to FIG. 7E, the inner pixel isolation structure may be formed in a form in which first pixel isolation structures (DTI1, DTI1′) having different structures are combined. For example, in each of the pixel blocks (PB_R, PB_Gr, PB_Gb, PB_B), the cross-shaped first pixel isolation structure (DTI1) may be formed in a region overlapping the central portion of the microlens 144, and the island-type first pixel isolation structures (DTI1′) may be formed in a region overlapping the edge portion of the microlens 144. In this case, the first pixel isolation structures (DTI1, DTI1′) and the outer pixel isolation structure (DTI_O) may be formed to be spaced apart from each other by a predetermined distance that allows the ion implantation regions formed by ions implanted through the PLAD process to contact each other.

As is apparent from the above description, the image sensing device based on some implementations of the disclosed technology can increase the use efficiency of incident light by improving a pixel isolation structure.

The embodiments of the disclosed technology may provide a variety of effects capable of being directly or indirectly recognized through the above-mentioned patent document.

Although a number of illustrative embodiments have been described, it should be understood that various modifications or enhancements of the disclosed embodiments and other embodiments can be devised based on what is described and/or illustrated in this patent document.

What is claimed is:

1. An image sensing device comprising:
a plurality of pixel blocks arranged in a first direction and a second direction perpendicular to the first direction, each pixel block including a microlens and a plurality of adjacent unit pixels that receives incident light via the microlens and each unit pixel structured to produce an electrical signal in response to received incident light therein;
an outer pixel isolation structure disposed between adjacent pixel blocks of the plurality of pixel blocks to isolate the adjacent pixel blocks from each other; and
an inner pixel isolation structure disposed between adjacent unit pixels of the unit pixels within each pixel block to isolate the adjacent unit pixels from each other,
wherein the inner pixel isolation structure includes a first pixel isolation structure having a different structure from the outer pixel isolation structure.

2. The image sensing device according to claim 1, wherein:
the first pixel isolation structure is disposed to overlap a central portion of the microlens.

3. The image sensing device according to claim 2, wherein the first pixel isolation structure includes:
a cross-shaped structure that includes a first portion extending in a line shape in the first direction and a second portion extending in a line shape in the second direction, wherein the first portion and the second portion are arranged to cross each other at a central portion of each of the pixel blocks.

4. The image sensing device according to claim 3, wherein the inner pixel isolation structure further includes:
a second pixel isolation structure having a same structure as the outer pixel isolation structure, and extending in a line shape between the outer pixel isolation structure and the first pixel isolation structure.

5. The image sensing device according to claim 4, wherein:
the second pixel isolation structure is connected to the outer pixel isolation structure and the first pixel isolation structure.

6. The image sensing device according to claim 4, wherein:
the second pixel isolation structure is isolated from the first pixel isolation structure while being connected to the outer pixel isolation structure.

7. The image sensing device according to claim 4, wherein:
each of the first portion and the second portion extends in a smaller width than the second pixel isolation structure.

8. The image sensing device according to claim 7, wherein the second pixel isolation structure includes:
an insulation material formed at sidewalls of a pixel isolation trench; and
a conductive material disposed between the insulation materials to gap-fill the pixel isolation trench,
wherein each of the first portion and the second portion is formed to have a width that is less than or equal to twice a thickness of the insulation material.

9. The image sensing device according to claim 3, wherein:
the first portion and the second portion extends to a region overlapping an edge portion of the microlens.

10. The image sensing device according to claim 9, wherein:
the first portion and the second portion are connected to the outer pixel isolation structure.

11. The image sensing device according to claim 9, wherein:
the first portion and the second portion are isolated from the outer pixel isolation structure.

12. The image sensing device according to claim 2, wherein the first pixel isolation structure includes:
a plurality of island-type pixel isolation structures arranged to be spaced apart from each other by a predetermined distance in the first direction and the second direction.

13. The image sensing device according to claim 12, further comprising:
a second pixel isolation structure having a same structure as the outer pixel isolation structure, and extending in a line shape between the outer pixel isolation structure and the first pixel isolation structure.

14. The image sensing device according to claim 12, wherein:
the plurality of island-type pixel isolation structures is arranged to extend to a region overlapping an edge portion of the microlens.

15. The image sensing device according to claim 2, wherein the first pixel isolation structure includes:
a cross-shaped structure in a region overlapping the central portion of the microlens, wherein the cross-shaped structure includes a first portion extending in a line shape in the first direction and a second portion extending in a line shape in the second direction cross each other; and
a plurality of island-type pixel isolation structures arranged to be spaced apart from each other by a predetermined distance in a region overlapping an edge portion of the microlens.

16. The image sensing device according to claim 1, wherein:
the outer pixel isolation structure includes a structure that includes a pixel isolation trench gap-filled with an insulation material and a conductive material; and
the first pixel isolation structure includes a structure that includes a pixel isolation trench gap-filled with the insulation material without the conductive material.

17. The image sensing device according to claim 16, wherein:
the conductive material includes at least one of polysilicon or a metallic material; and
the insulation material includes an oxide layer.

18. An image sensing device comprising:
a plurality of unit pixels including a same color filter for filtering incident light to be detected by the unit pixels and configured to share a microlens that direct the incident light into the unit pixels, each of the plurality of unit pixels including a photoelectric conversion element configured to convert received incident light into an electrical signal representing received light at the unit pixel; and
a pixel isolation structure disposed between the photoelectric conversion elements of the plurality of unit pixels,
wherein the pixel isolation structure includes:
a first pixel isolation structure disposed to overlap a central portion of the microlens; and
a second pixel isolation structure disposed to overlap an edge portion of the microlens and configured to have a different structure from the first pixel isolation structure.

19. The image sensing device according to claim 18, wherein the second pixel isolation structure includes:
an insulation material formed at sidewalls of a second pixel isolation trench; and
a conductive material disposed between the insulation materials to gap-fill the second pixel isolation trench,
wherein the first pixel isolation structure includes a structure in which a first pixel isolation trench is gap-filled with the insulation materials without the conductive material.

20. The image sensing device according to claim 19, wherein:
the conductive material includes at least one of polysilicon or a metallic material; and
the insulation material includes an oxide layer.
